(19) United States
(12) Patent Application Publication
(10) Pub. No.: US 2002/0167071 A1
(43) Pub. Date: Nov. 14, 2002

(54) Guard ring for protecting integrated circuits

(76) Inventor: Mu-Chun Wang, Hsin-Chu Hsien (TW)

Correspondence Address: NAIPO (NORTH AMERICA INTERNATIONAL PATENT OFFICE), P.O. BOX 506, MERRIFIELD, VA, 22116, US

(21) Appl. No.: 09/851,577

(22) Filed: May 10, 2001

(51) Int. Cl. H01L 23/544

(52) U.S. Cl. 257/620

(57) ABSTRACT

The present invention gives a semiconductor chip device having an integrated circuit region fabricated on a substrate, a street region surrounding the integrated circuit region, a first guard ring formed between the integrated circuit region and the street region, and a second guard ring formed between the first guard ring and the street region. The first guard ring and the second guard ring are a collection of discontinuous dam-shaped stacks to prevent die cracking when sawing the wafer.

### BACKGROUND OF THE INVENTION

1. Field of the Invention

The present invention relates to a guard ring structure of a semiconductor chip device, and more particularly, to a discontinuous dam-shaped guard ring structure for preventing occurrence of chip cracking.

2. Description of Prior Art

The manufacturing flow of the integrated circuit can be mainly distinguish into three stages as follow: (1) the manufacture of the silicon wafer, (2) the fabrication of the integrated circuit, and (3) sawing, electric test, sorting and packaging of the integrated circuit. When fabricating the integrated circuit on the silicon wafer, the whole silicon wafer is divided uniformly into many overlapping dies, and the adjacent dies are separated by a scribe line or street. The sawing step of the integrated circuit utilizes a cutter to saw the silicon wafer into individual dies along the scribe lines or streets. In generally, an 8-inch single crystal silicon wafer is divided into hundreds of dies, each die about 1 to 2 centimeters squared. Furthermore a developing 12-inch silicon wafer can be divided into even more dies about 2.5 times that of the 8-inch silicon wafer.

In recent years, the semiconductor process of deep sub-micro with high integration below 0.18 micrometers, with a inter metal dielectric (IMD) layer collocated by the dual damascene technology and use of low dielectric materials is the most popular metal interconnects technology to date. Due to the low resistance of cooper, and the low dielectric material, the RC delay between the metal wires is greatly reduced. But many of the low dielectric materials (especially the organic low dielectric materials) are fragile. Therefore chip cracking often occurs by sawing side stress when sawing the die. The chip cracking causes many infant moralities in products so reducing yield in subsequent electric test processes. In addition, moisture can permeate into the integrated circuit along the chip cracking to corrode the metal wires and cause the integrated circuit to breakdown in reliability test processes.

In order to cushion the sawing stress and prevent the effects of the chip cracking of the integrated circuit, a metal guard ring surrounding the integrated circuit is formed between the integrated circuit and the street region of the silicon wafer simultaneously in the metallization process of the integrated circuit. Please refer to FIG. 1 of an amplified top view of a die 10. As shown in FIG. 1, the die 10 comprises a silicon substrate 12, an integrated circuit region 16 fabricated on a surface of the silicon substrate 12, a metal guard ring 15 surrounding the integrated circuit region 16. The street region 14 surrounds the die 10. A buffer region 13a is formed between the integrated circuit region 16 and the metal guard ring 15, and a buffer region 13b is formed between the street region 14 and the metal guard ring 15.

Please refer to FIG. 2 of a cross-sectional schematic diagram along a section line I-I′ of a metal guard ring shown in FIG. 1. As mentioned, the prior art method for forming a guard ring of the die 10 involves patterning the metal guard ring surrounding the die 10 in a metallization process. As shown in FIG. 2, an upper part of the silicon substrate 12 is covered with a dielectric layer 22, and serves as the integrated circuit region 16, the buffer region 13a, the guard ring structure 15 and the buffer region 13b as shown in FIG. 1. The guard ring 15 is stacked by the a first wire-metal layer (M-1) 32 forming in a first IMD layer 24, a first via-metal layer (VIA-1) 34 forming in a second IMD layer 26, a second wire-metal layer (M-2) 36 forming in a third IMD layer 28, and a second via-metal layer (VIA-2) 38 forming in a fourth IMD layer 30, respectively.

In general, the first IMD layer 24, the second IMD layer 26, the third IMD layer 28 and the fourth IMD layer 30 are all composed of the fragile organic low dielectric materials, such as SiLK™, or some other polymer-type organic low dielectric constant material. Sometimes more than two metal guard rings are utilized in order to resist sawing stress, in other words a second metal guard ring is further formed between the first metal guard ring and the street region.

However, the metal guard ring structure of the die of the prior art has several disadvantages including: (1) parts of the metal guard ring are a continues structure, it may cause current leakage and reduce the reliability of the integrated circuit, (2) the method for forming the guard ring of the die is patterning the metal guard ring surrounding the die in the metallization process, however it cannot prevent the occurrence of chip cracking in the dielectric layer 22, (3) the guard ring is not hard enough.

### SUMMARY OF THE INVENTION

It is therefore an object of the present invention to provide a discontinuous dam-shaped guard ring structure to increase the reliability of the product.

The present invention relates to a guard ring structure of a semiconductor chip device. The semiconductor chip device comprises a substrate, an integrated circuit region fabricated on the substrate, a street region surrounding the integrated circuit region and at least one discontinuous guard ring structure formed between the integrated circuit region and the street region. The discontinuous guard ring structure comprises a first dam-shaped stack with a length L and a second dam-shaped stack laterally deposited at one side of the first dam-shaped stack. Wherein, the first dam-shaped stack and the second dam-shaped stack are isolated from each other by a plurality of layers of dielectric materials.

It is another objective of the present invention to provide a semiconductor chip device comprising an integrated circuit region fabricated on the silicon substrate, a street region surrounding the integrated circuit region and a first guard ring deposited between the integrated circuit region and the street region, and a second guard ring deposited between the first guard ring and the street region. Wherein both the first guard ring and the second guard ring are composed of a plurality of discontinuous dam-shaped stacks.

Wherein the first guard ring comprises a first dam-shaped stack and a second dam-shaped stack, and the second guard ring comprises a third dam-shaped stack, and the third dam-shaped stack overlapping an inter-stack space between the first dam-shaped stack and the second dam-shaped stack.

Wherein the first dam-shaped stack, the second dam-shaped stack and the third dam-shaped stack all have a length L, and the length of the inter-stack space between the first dam-shaped stack and the second dam-shaped stack is L/2. An overlapping length of the third dam-shaped stack and the first dam-shaped stack is L/4.

These and other objectives of the present invention will no doubt become obvious to those of ordinary skill in the art after reading the following detailed description of the preferred embodiment, which is illustrated in the multiple figures and drawings.

### BRIEF DESCRIPTION OF THE DRAWINGS

FIG. 1 is an amplified top view of a die according to the prior art.

FIG. 2 is a cross-sectional schematic diagram along a section line I-I′ of a metal guard ring shown in FIG. 1.

FIG. 3 is an amplified top view of the die according to the present invention.

FIG. 4 is a cross-sectional schematic diagram along a section line II-II′ of the guard ring shown in FIG. 3.

FIG. 5 is a top view of the second preferred embodiment of the die according to the present invention.

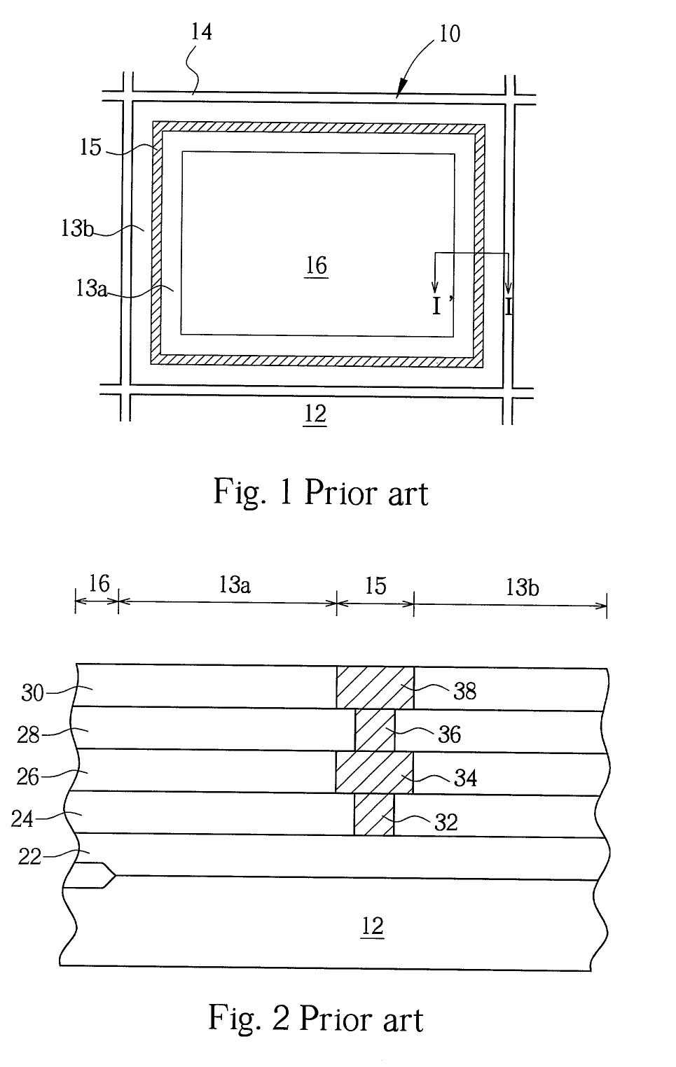

### DETAILED DESCRIPTION OF THE PREFERRED EMBODIMENT

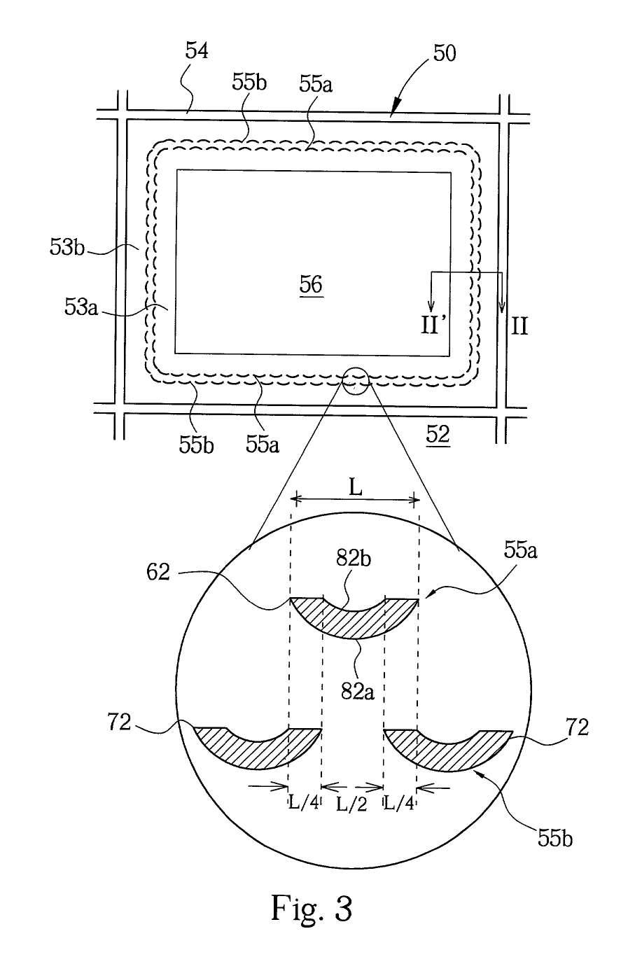

Please refer to FIG. 3 of an amplified top view of a die 50. A s shown in FIG. 3, the die 50 of the present invention comprises a silicon substrate 52, an integrated circuit region 56 fabricated on a surface of the silicon substrate 52, a dam-shaped guard ring structure 55a and a dam-shaped guard ring structure 55b surrounding the integrated circuit region 56. A street region 54 is surrounding the die 50 similarly. A buffer region 53a is located between the integrated circuit region 56 and the guard ring structure 55a, and a buffer region 53b is located between the street region 54 and the guard ring structure 55b. In the present invention, the guard ring structure 55a and the guard ring structure 55b both consist of a plurality of discontinuous dam-shaped stacks, with the guard ring structure 55a and the guard ring structure 55b overlap each other.

A partial discontinuous guard ring structure 55a and a partial discontinuous guard ring structure 55b are shown below of the amplified top view (as shown in the circle) . To simplify the present invention, only one dam-shaped stack 62 and two dam-shaped stacks 72 of the guard ring structure 55b are shown in the amplified top view of FIG. 3. In a preferred embodiment of the present invention, the dam-shaped stack 62 and the dam-shaped stack 72 have both a length L, the length of the inter-stack space between two of the dam-shaped stacks 72 is about L/2, and the overlapping length of the dam-shaped stack 62 and the dam-shaped stack 72 is about L/4. Preferably the length L is about 0.1 to 5 micrometers, and the length between the dam-shaped stack 62 and the dam-shaped stack 72 is about 0.5 to 1.5 micrometers, preferably 1 micrometer.

Furthermore, another feature of the present invention is that the dam-shaped stack 62 and the dam-shaped stack 72 both comprise a first curved wall 82a having a first radius of curvature and second curved wall 82b having a first radius of curvature. Wherein, the first radius of curvature is greater than the second radius of curvature. More importantly the second curved wall 82b having a lower first radius of curvature faces the integrated circuit region 56 and the first curved wall 82a having a higher first radius of curvature faces the street region 54. Due to the particularly dam-shaped shape of the guard ring structure 55a and the guard ring structure 55b, the first curved wall 82a that faces the street region 54 can handle larger stress. Therefore it resists the sawing stress much better.

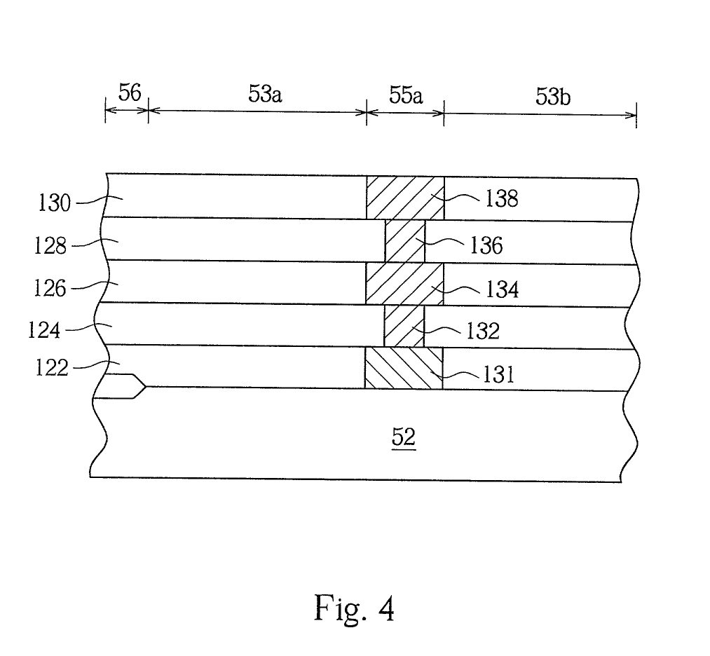

Please refer to FIG. 4 of a cross-sectional schematic diagram along a section line II-II′ crossing one dam-shaped stack of the guard ring structure 55a shown in FIG. 3. As shown in FIG. 4, an upper part of the silicon substrate 52 is covered with a dielectric layer 122, and serves as the integrated circuit region 56, the buffer region 53a, the guard ring structure 55a and the buffer region 53b as shown in FIG. 3. The guard ring 55a is stacked by the polysilicon layer 131 forming in the dielectric layer 122, a first wire-metal layer (M-1) 132 forming in a first IMD layer 124, a first via-metal layer (VIA-1) 134 forming in a second IMD layer 126, a second wire-metal layer (M-2) 136 forming in a third IMD layer 128, and a second via-metal layer (VIA-2) 138 forming in a fourth IMD layer 130, respectively. The dielectric layer 122, the first IMD layer 124, the second IMD layer 126, the third IMD layer 128 and the fourth IMD layer 130 are all composed of fragile organic low dielectric materials, such as SiLK™, or some other polymer-type organic low dielectric material. In addition, a passivation layer (not shown) is further formed on top of the guard ring structure 55a.

The difference between the metal guard ring of the prior art and the present invention, is that each of the dam-shaped stack of the guard ring structure are stacked above the polysilicon layer (PL1) 131. The polysilicon layer 131 is normally defined surrounding the die 50 as the gate element or the word-line is formed in the integrated circuit region 56, due to the simplicity of the formation of the polysilicon layer 131.

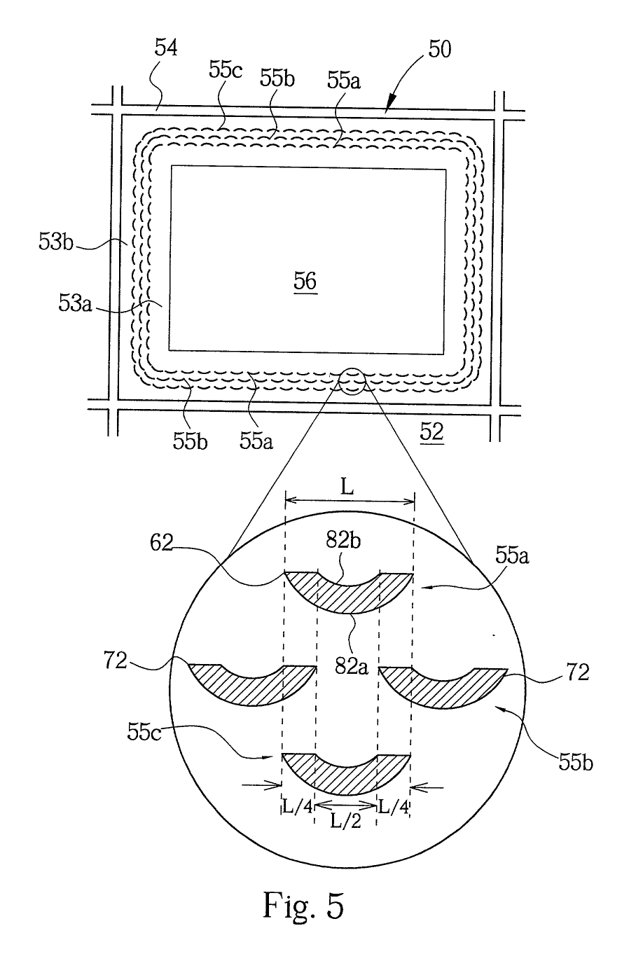

As shown in FIG. 5 of a top view of the second preferred embodiment of the die according to the present invention. The die 50 comprises a silicon substrate 52, an integrated circuit region 56 fabricated on the surface of the silicon substrate 52, the dam-shaped guard ring structure 55a, the dam-shaped guard ring structure 55b, and the dam-shaped guard ring structure 55c surrounding from inside to outside the integrated circuit region 56. The guard ring structure 55a, the guard ring structure 55b, and the guard ring structure 55c consist of a plurality of discontinuous dam-shaped stacks, and the guard ring structure 55a. The guard ring structure 55b, and the guard ring structure 55c overlap each other. The overlapping mode is similar to the preferred embodiment in the present invention. However, the present invention can have a plurality of guard ring structures formed simultaneously surrounding the region of the die 50 and is not limited in the preferred and the second preferred embodiment.

In comparison with the prior art, the guard ring structure 55a, the guard ring structure 55b, and the guard ring structure 55c are all dam-shaped in the present invention. The first curved wall 82a that faces the street region 54 handles larger stress to resist sawing stress. The guard ring structure 55a, the guard ring structure 55b and the guard ring structure 55c are all composed of the discontinuous dam-shaped stack 62 and the discontinuous dam-shaped stack 72, and the arrangement of the discontinuous dam-shaped stack 62 and the discontinuous dam-shaped stack 72 overlap each other for the best protection of the guard ring structure. Further, the dam-shaped stack 62 and the dam-shaped stack 72 are both stacked above the polysilicon layer 121 to efficiently prevent the integrated circuit region 56 from die cracking.

Those skilled in the art will readily observe that numerous modification and alterations of the device may be made while retaining the teachings of the invention. Accordingly, the above disclosure should be construed as limited only by the metes and bounds of the appended claims.

What is claimed is:

1. A discontinuous guard ring structure of a semiconductor chip device, the semiconductor chip device comprising a substrate, an integrated circuit region fabricated on the substrate, a street region surrounding the integrated circuit region, and at least one discontinuous guard ring structure formed between the integrated circuit region and the street region, the discontinuous guard ring structure comprising:
a first dam-shaped stack with a length L; and
a second dam-shaped stack laterally deposited at one side of the first dam-shaped stack;
wherein the first dam-shaped stack and the second dam-shaped stack are isolated from each other by a plurality of layers of dielectric material.

2. The discontinuous guard ring structure of claim 1 wherein the first dam-shaped stack and the second dam-shaped stack both comprise a first curved wall having a first radius of curvature and second curved wall having a second radius of curvature.

3. The discontinuous guard ring structure of claim 2 wherein the first radius of curvature is greater than the second radius of curvature.

4. The discontinuous guard ring structure of claim 2 wherein the second curved wall faces the integrated circuit region and the first curved wall faces the street region.

5. The discontinuous guard ring structure of claim 1 wherein the first dam-shaped stack and the second dam-shaped stack both comprise a polysilicon layer, at least one via-metal layer, and at least one wire-metal layer.

6. The discontinuous guard ring structure of claim 1 wherein the distance between the first dam-shaped stack and the second dam-shaped stack is about L/2.

7. A semiconductor chip device comprising:
an integrated circuit region fabricated on a substrate;
a street region surrounding the integrated circuit region;
a first guard ring deposited between the integrated circuit region and the street region; and
a second guard ring deposited between the first guard ring and the street region;
wherein both the first guard ring and the second guard ring are composed of a plurality of discontinuous dam-shaped stacks.

8. The semiconductor chip device of claim 7 wherein the first guard ring comprises a first dam-shaped stack and a second dam-shaped stack, and the second guard ring comprises a third dam-shaped stack, the third dam-shaped stack overlapping an inter-stack space between the first dam-shaped stack and the second dam-shaped stack.

9. The semiconductor chip device of claim 8 wherein the first dam-shaped stack, the second dam-shaped stack and the third dam-shaped stack have a length L, and the length of the inter-stack space between the first dam-shaped stack and the second dam-shaped stack is about L/2.

10. The semiconductor chip device of claim 8 wherein an overlapping length of the third dam-shaped stack and the first dam-shaped stack is about L/4.

11. The semiconductor chip device of claim 8 wherein each of the first dam-shaped stack, the second dam-shaped stack and the third dam-shaped stack comprises a first curved wall having a first radius of curvature and second curved wall having a second radius of curvature.

12. The semiconductor chip device of claim 11 wherein the first radius of curvature is greater than the second radius of curvature.

13. The semiconductor chip device of claim 11 wherein the second curved wall faces the integrated circuit region.

14. The semiconductor chip device of claim 8 wherein each of the first dam-shaped stack, the second dam-shaped stack and the third dam-shaped stack comprises a polysilicon layer, at least one via-metal layer, and at least one wire-metal layer.
